(19) United States
(12) Patent Application Publication
(10) Pub. No.: US 2016/0227660 A1
(43) Pub. Date: Aug. 4, 2016

(54) ASSEMBLY OF MODULES, MODULE SUPPORT AND MODULE

(71) Applicant: ALSTOM Technology Ltd, Baden (CH)

(72) Inventors: Roman RAUBO, Downingtown, PA (US); Marek FURYK, Boyertown, PA (US)

(21) Appl. No.: 14/613,312

(22) Filed: Feb. 3, 2015

(51) Int. Cl. H05K 5/02

(52) U.S. Cl. CPC H05K 5/0247; H05K 5/0221

(57) ABSTRACT

An assembly of modules for an electrical circuit comprising: a module support for at least two modules and at least two modules, each module comprising two complementary connectable sub-modules. The module support comprises for each sub-module at least an alignment member adapted to individually align the sub-module during its installation on the module support in such way to connect it to complementary sub-module already installed on the module support to form one of the modules.

### TECHNICAL DOMAIN

The invention relates to the domain of the high voltage circuits such as voltage-source converters, and more precisely to the module support which support the modules that equip such high voltage circuits.

### PREVIOUS ART

A high voltage circuit, such as a voltage-source converter or a flexible alternative current transmission system, comprises usually many elements that can be arranged in modules. Such an element, or module, can comprise two complementary connectable sub-modules: an electrical device sub-module, such as including a direct current capacitor (also known as a DC capacitor), and a front end sub-module for the connection of the electrical device sub-module to the remaining of the high voltage circuit.

For example and for a voltage source-converter, such a module can be a full bridge/DC capacitor module in which the device is a DC capacitor and the front end sub-module is a full bridge sub-module with which it is possible to control, in use, the polarity of the connection between the DC capacitor and the remaining of the voltage source-converter. Usually, the complementary sub-modules that form a module are packed together in one package in a casing.

A high voltage circuit also comprises a module support, such as a stack frame, to support and connect all the modules. In this way, when the circuit is built, all the modules are placed on the module support each one, at a corresponding location on the module support, and are connected to the other modules to form the high voltage circuit.

With this configuration, a high voltage circuit is easily repairable thanks to the possibility to replace each module or sub-module by a new one. However, this configuration has some drawbacks as the installation is particularly difficult due to the weight of a module (around 150 kg) and to the height of the module support at which a module can be installed. Furthermore, even if it is necessary to change only one sub-module of a module it is required to remove the entire module from the module support.

### PRESENTATION OF THE INVENTION

The invention is aimed to resolve these drawbacks.

In this purpose, the invention relates to an assembly of modules for an electrical circuit, such as a Flexible Alternative Current Transmission Systems, called FACTS, comprising:
a module support for at least two modules,
at least two modules, each module comprising two complementary connectable sub-modules: an electrical device sub-module, such as including a direct current capacitor; and a front end sub-module intended to connect in use the electrical device sub-module to the remaining of the electrical circuit.

Wherein the module support comprises for each sub-module:
at least an alignment member adapted to individually align the sub-module during its installation on the module support in such way to connect it to a complementary sub-module already installed on the module support to form one of the modules.

Such an assembly makes easier the building of an electrical circuit such as a voltage-source converter or a FACTS, since for mounting the modules of the assembly on the module support it is possible to mount individually each sub-module and form the module directly on the module support. In this way, the technician just has to manipulate the weight of only one sub-module at the time when it is required to mount a module at height. Furthermore, such assembly facilitates also the maintenance of the electrical circuit by allowing the change of one of the sub-modules that form a module without requiring moving the complementary sub-module. The new sub-module just has to be mounted at the location of the defective one to obtain an operative module.

The alignment member could also be adapted to support the sub-module to align.

The alignment means could be adapted to hang the sub-module to align.

Each alignment member could comprises a rod, each sub-module comprising a complementary hole to the rod of the corresponding alignment member so to hang it on the module support when installed on the module support.

Such alignment members allow to mount, align and connect the sub-modules in two simple steps of putting each sub-module on the corresponding alignment members.

The module support could comprise at least two rods, one for each sub-modules of the module, which are extended in opposite directions from each other.

With such configuration, the two rod opposite to each other allow a good alignment between the two modules.

Each alignment member could comprise at least a hole, each sub-module comprising a complementary rod to the hole of the corresponding alignment member so to hang it on the module support when installed on the module support.

Such alignment members allow to mount, align and connect the sub-modules in two simple steps of putting each sub-module on the corresponding alignment members.

Each sub-module could comprise at least an electrical connector complementary to electrical connector of the complementary sub-module to electrically connect them together during the alignment on the module support.

Each module could comprises an installation jig for guiding the front end sub-module when it is mounted on the module support.

Such installation jig allow an easy mounting of a sub-module on the module support.

The invention is also related on a module support for an electrical circuit, such as a Flexible Alternative Current Transmission Systems, called FACTS, which is for at least two modules, and that is characterized in that it is adapted to support modules which comprising two complementary connectable sub-modules: an electrical device sub-module, such as including an direct current capacitor; and a front end sub-module intended to connect in use the electrical device sub-module to the remaining of the electrical circuit;
wherein the module support comprises for each module it is intended to support:
   two alignment members each one adapted to individually align a sub-module during its installation on the module support in such way to connect it to an complementary sub-module already installed on the module support to form the module.

Such module support allow the formation of a module of the invention that benefit from the advantage of the invention.

The invention is also related on a module for an electrical circuit, such as a Flexible Alternative Current Transmission Systems, called FACTS, that comprises two individual complementary connectable sub-modules: an electrical device sub-module, such as including a direct current capacitor; and a front end sub-module intended to connect in use the electrical device sub-module to the remaining of the electrical circuit. Each sub-modules is adapted to be individually mounted on a module support that comprises an alignment member adapted to individually align a sub-module during its installation on the module support in such way to connect it to a complementary sub-module already installed on the module support to form one of the modules.

The invention also related on Flexible Alternative Current Transmission Systems that comprise an assembly of modules. The assembly of modules is the assembly of modules of the invention.

Such FACTS device benefit from the advantages of the assembly of modules that it comprises.

### BRIEF DESCRIPTION OF THE DRAWINGS

The present invention will be better understood with the reading of the specification of a furnished embodiment which does not limit the scope of the invention. This specification refers to the annexed drawings in which:

FIG. 1 shows a module support on which a first sub-module is mounted and a second one, complementary to the first one, is in a position intended to be mounted on the module support to form a module,

FIG. 2 is a close view of the module support of FIG. 1 with the first and the second sub-module intended to be mounted on the module support.

Same or similar parts in the different drawings use the same numerical reference to make easier the passage from one drawing to another.

### DETAILED PRESENTATION OF PARTICULAR EMBODIMENTS

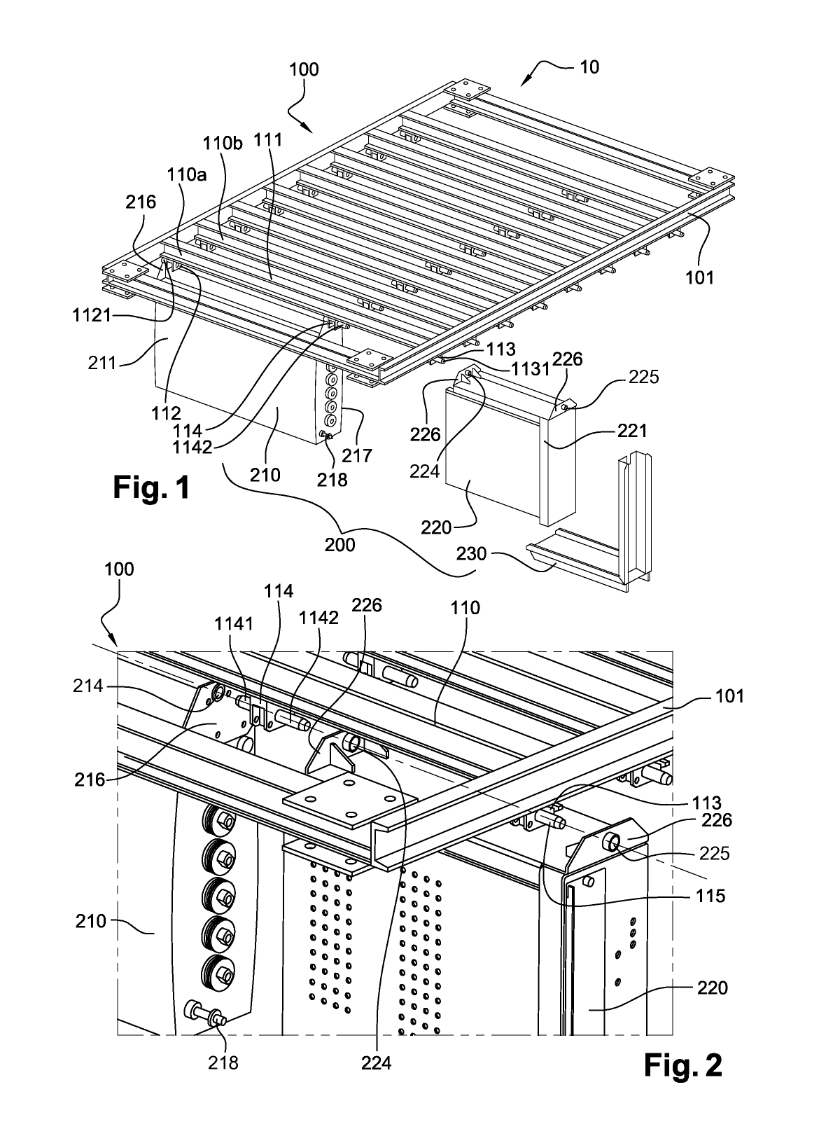

FIG. 1 shows a module support 100 of the invention on which a sub-module, which is an electrical device sub-module 210, is mounted and a complementary sub-module, which is a front end sub-module 220, is in a position intended to be mounted on the module support 100 to form a module 200 when it will be connected on the electrical device sub-module 210.

The module support 100 illustrated on FIG. 1 has a generally rectangular shape and comprises a frame 101 and eight module locations 110a, 110b allocated along the length of the module support 100.

Each module location 110a, 110b comprises a support bar 111 that extends along the width of the module support 100. Each support bar 111 is provided with three extensions 112, 113, 114 with a first and a second extension each one on an extremity of the support bar 111 and a third one on a central part of the support bar 111. Each third extension 114 delimits together with corresponding first extension 112 a first portion of the corresponding support bar 111 that is intended to support an electrical device sub-module 210. Each third extension 114 delimits together with corresponding second extension 113 a second portion of the corresponding support bar 111 that is intended to support a front end sub-module 220.

Each extension 112, 113, 114 protrudes from the support bar 111 perpendicular to the plan of the module support 100 in such way that said extension 112, 113, 114 extends, when the module support 100 is mounted, in direction of the ground.

Each extension 112, 113, 114 comprises at least a rod 1121, 1131, 1141, 1142 that extends parallel to the corresponding support bar 111. More precisely, the first and second extensions 112, 113 comprise each one a rod whereas the third extensions comprise two rods.

The rod 1121 of each first extension 112 and one of the rods 1141, 1142 of the third extension 114 extend from the corresponding extension 112, 114 in a direction that goes from the second extension 113 to the first extension 112. The rod 1131 of the second extension 113 and the other rod 1142 of the third extension 114 extend from the corresponding extension 113, 114 in the direction that goes from the first extension 112 to the second extension 113.

The rods 1121, 1131, 1141, 1142 allow the mounting of the sub-modules on the module support 100 to form the modules 200. The rods 1121, 1131, 1141, 1142 also form alignment members that are adapted to allow the alignment of sub-modules 210, 220 during their installation on the module support 100 in such way to connect them to complementary sub-modules 220, 210 already installed on the module support 100 to form the modules. Such alignment members are also adapted, as shown on FIG. 1, to support sub-modules by hang them.

To allow this cooperation between the rods of the module locations and the sub-modules, each sub-module comprises, as illustrated on FIG. 2, two holes 214, 224, 225.

The two sub-modules illustrate on FIG. 2, similarly to the ones of the previous art, are an electrical device sub-module 210 and a front end sub-module 220 to form together a module 200 when they are supported by the module support 100. Each sub-module 210, 220 differs from the one of the previous art by comprising an individual casing 211, 221, electrical connectors that are complementary than the ones of the other type of sub-modules and the holes 214, 224, 225 which are adapted to cooperate with the rods 1121, 1131, 1141, 1142 of a module location 110a, 110b of the module support 100.

A sub-module 210, 220, as illustrated on FIG. 2, presents, thanks to its casing, a generally rectangular cuboid shape with a longitudinal direction. On the top of the casing, each sub-module 210, 220 comprises two wings 216, 226.

The two wings 216, 226 of each sub-module extend upward parallel to each other from the top of the casing when the sub-module is mounted on the module support 100. The wings 216, 226 are planar and perpendicular to the longitudinal direction of the sub-module that comprises them. Each wing 216, 226 comprises one of the hole 214, 224, 225 of the corresponding sub-module 210, said hole 214, 224, 225 being a through hole.

Each sub-module 210, 220 also comprises electrical connectors 217, 218 to electrically connect the sub-module 210, 220, during its installation on the module support 100, to a complementary sub-module 220, 210 already installed on the module support 100. To furnish this connection, these electrical connectors 217, 218 are complementary to electrical connectors 217, 218 of the complementary sub-module 220, 210 to allow the connection by the mounting on the module support 100.

As shows on FIGS. 1 and 2, the electrical device sub-module 210 comprises six female connectors 217 and one male connector 218 of the snap on type. In the same way, the front end sub-module comprises six male connectors and one female connector of the snap on type which are not show on the figure. The six male connectors and the one female connector of the front end sub-module 220 are arranged in such way they are facing a complementary connector 217, 218 of the electrical device sub-module 210 when both sub-modules 210, 220 are mounted on the module support 100 to form a module 200.

The module 200, shows on FIG. 1, also comprises an installation jig 230 for guiding the front end sub-module when it is mounted on the module support 100.

The module support 100 together with at least two modules form an assembly of modules 10.

Such assembly of modules 10 can be mounted by using a mounting method that comprises the following steps:
furnishing the module support 100 and at least two electrical device sub-modules 210,
mounting the electrical device sub-modules 210 on the first portion of the corresponding support bar 111 of the module support 100 by placing the electrical device sub-modules in such way to insert rods of the corresponding support bar 111 into the holes of the electrical device sub-modules 210,
furnishing the same amount of front end sub-modules 220 than the electrical device sub-modules 210,
mounting the front end sub-modules on the second portion of the corresponding support bar 111 on which an electrical device sub-modules 210 has already been mounted in such way to insert rods of the corresponding support bar 111 into the holes of the electrical device sub-modules and to connect the electrical connectors of the front end sub-modules with the ones of the corresponding electrical device sub-module 210.

With such configuration of the module assembly 10, all the sub-modules are perfectly aligned with a complementary sub-module. This alignment allows the connection of the electrical connectors of the sub-modules with the electrical connectors of the complementary sub-module and so the formation of the modules.

Such assembly of modules 10 can be used to at least partly form an electrical circuit such as an FACTS device as a source-voltage converter.

In another embodiment of the invention, not illustrated, the support bar 111 comprises holes on each extension 112, 113, 114 instead of the rods 1121, 1131, 1141, 1142 the sub-modules 210, 220 comprising on each wing 216, 226 a rod that is complementary than the holes of the corresponding support bar 111. Such holes could be passing through hole.

The invention does not limit to the use of alignment members which are rods 1121, 1131, 1141, 1142 or holes 214, 224, 225 but extend to the use of every type of alignment members which can be used to align a sub-module 210, 220 on a module support 100. For example, such alignment members can be rails or some lateral guides without extending beyond the scope of the invention.

1. An assembly of modules for an electrical circuit, such as a Flexible Alternative Current Transmission Systems, comprising:
a module support for at least two modules,
at least two modules, each module comprising two complementary connectable sub-modules: an electrical device sub-module, including a direct current capacitor; and a front end sub-module to connect in use the electrical device sub-module to the remaining of the electrical circuit,
the module support comprises for each sub-module:
at least an alignment member adapted to individually align the sub-module during its installation on the module support in such way to connect it to complementary sub-module already installed on the module support to form one of the modules.

2. The assembly of modules of claim 1, wherein the alignment member is adapted to support the sub-module to align.

3. The assembly of modules of claim 2, wherein the alignment means is adapted to hang the sub-module to align.

4. The assembly of modules of claim 3, wherein each alignment member comprises a rod, each sub-module comprising a complementary hole to the rod of the corresponding alignment member so to hang it on the module support when installed on the module support.

5. The assembly of modules of claim 4, wherein for a module, the module support comprises at least two rods, one for each sub-modules of the module, which are extended in opposite directions from each other.

6. The assembly of modules of claim 3, wherein each alignment member comprises at least a hole, each sub-module comprising a complementary rod to the hole of the corresponding alignment member so to hang it on the module support when installed on the module support.

7. The assembly of modules of claim 1, wherein each sub-module comprises at least an electrical connector complementary to electrical connector of the complementary sub-module to electrically connect them together during the alignment on the module support.

8. The assembly of modules of claim 1, wherein each module comprises an installation jig for guiding the front end sub-module when it is mounted on the module support.

9. A module support for an electrical circuit, such as a Flexible Alternative Current Transmission Systems, which is for at least two modules, and is adapted to support modules comprising two complementary connectable sub-modules: an electrical device sub-module, including an direct current capacitor; and a front end sub-module to connect in use the electrical device sub-module to the remaining of the electrical circuit;
wherein the module support comprises for each module to support:
two alignment members each one adapted to individually align a sub-module during its installation on the module support to connect it to an complementary sub-module installed on the module support to form the module.

10. A Module for an electrical circuit, such as a Flexible Alternative Current Transmission Systems, comprising two individual complementary connectable sub-modules: an electrical device sub-module, including a direct current capacitor; and a front end sub-module to connect in use the electrical device sub-module to the remaining of the electrical circuit, and wherein each sub-modules is adapted to be individually mounted on a module support that comprises an alignment member adapted to individually align a sub-module during its installation on the module support to connect it to a complementary sub-module installed on the module support to form one of the modules.

11. Flexible Alternative Current Transmission Systems that comprise an assembly of modules having a module support for at least two modules,
at least two modules, each module comprising two complementary connectable sub-modules: an electrical device sub-module including a direct current capacitor; and a front end sub-module to connect in use the electrical device sub-module to the remaining of the electrical circuit,
the module support comprises for each sub-module:
an alignment member adapted to individually align the sub-module during its installation on the module support to connect it to complementary sub-module already installed on the module support to form one of the modules.
